(19) United States
(12) Patent Application Publication
(10) Pub. No.: US 2007/0045629 A1
(43) Pub. Date: Mar. 1, 2007

(54) White light LED

(75) Inventors: Yuan-Cheng Chin, Hsintien City (TW); Ching-Huei Wu, San Chung City (TW)

Correspondence Address: TROXELL LAW OFFICE PLLC;SUITE 1404, 5205 LEESBURG PIKE, FALLS CHURCH, VA, 22041, US

(73) Assignee: Unity Opto Technology Co., Ltd.

(21) Appl. No.: 11/192,277

(22) Filed: Jul. 29, 2005

(51) Int. Cl. H01L 27/108

(52) U.S. Cl. 257/68

(57) ABSTRACT

A white light LED (light emitting diode) is disclosed. The white light LED comprises: a bracing frame; at least an UV (or a blue light) chip mounted on the bracing frame; and a flat thin film stacked on the UV chip and formed by mixing a main agent and a solute uniformly for having uniform thickness and homogenized fluorescent powder, thereby forming the uniform white light free of photochromic difference or halation by passing the UV light emitted from the UV chip through the thin film.

### FIELD OF THE INVENTION

The present invention is related to a white light LED (light emitting diode) or the like for forming the uniform white light free of photochromic difference or halation.

### BACKGROUND OF THE INVENTION

In 1996, Nichia Chemical Industries in Japan developed a white light LED by covering a blue LED with phosphor (thereby mixing blue light and yellow light to create high brightness white light). The white light LED may replace the fluorescent lamp in the future to start the era of applying the white light LED to the illumination.

The white light is a mixture of multiple colored lights. The light mixture detectable by the human eye comprises at least two kinds of wavelengths. For example, the human eyes determine that it is white color when detecting red, blue and green colors or blue and yellow colors simultaneously. Accordingly, the white light LED can be designed based on this principle. In order to increase the color rendering of the conventional white light LED that has three wavelengths, at least three kinds of fluorescent powders must be applied to the manufacture. Accordingly, the difficulty in selection of the fluorescent powders is increased.

Nevertheless, referring to FIG. 3, a conventional white light LED is shown, wherein a colored chip B such as blue light chip is fixedly mounted on a recess of a frame A, and the colored chip B is connected to another frame D by a leading wire C. Thereafter, a layer of fluorescent adhesive F is filled into the recess. The upper portions of the frame A, D are covered with a transparent layer E to complete the manufacture of the white light LED. Generally speaking, the fluorescent powders inside the fluorescent adhesive layer F are provided with different disposition rates. Accordingly, the major drawback of the conventional white light LED consists in the generation of photochromic difference and halation by non-equivalent density dispersion of fluorescent powders and uneven thickness of fluorescent adhesive layer if the white light LED is electrified.

In view of the drawback of the conventional structure, the present inventor makes a diligent study to disclose and fabricate a white light LED, thereby providing the uniform white light free of photochromic difference or halation for the consumer in accordance with the motive of the present invention.

### SUMMARY OF THE INVENTION

It is a main object of the present invention to provide a white light LED for forming the uniform white light free of photochromic difference or halation.

In order to achieve the aforementioned object, a white light LED is disclosed. The white light LED comprises: a bracing frame; at least an UV (or a blue light) chip mounted on the bracing frame; and a flat thin film stacked on the UV chip and formed by mixing a main agent and a solute uniformly for having uniform thickness and homogenized fluorescent powder, thereby forming the uniform white light free of photochromic difference or halation by passing the UV light emitted from the UV chip through the thin film.

The aforementioned aspects and advantages of the present invention will be readily clarified in the description of the preferred embodiments and the enclosed drawings of the present invention.

### BRIEF DESCRIPTION OF THE DRAWINGS

FIG. 1 is a schematic cross-sectional diagram showing partial structure of one preferred embodiment of present invention.

FIG. 2 is a schematic cross-sectional diagram showing partial structure of another preferred embodiment of present invention.

FIG. 3 is a cross-sectional diagram showing a conventional white light LED.

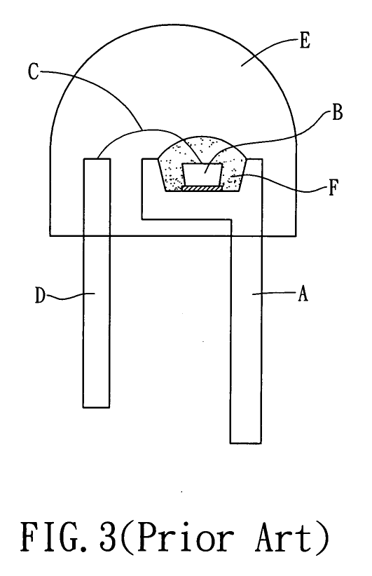

### DETAILED DESCRIPTION OF THE PREFERRED EMBODIMENT

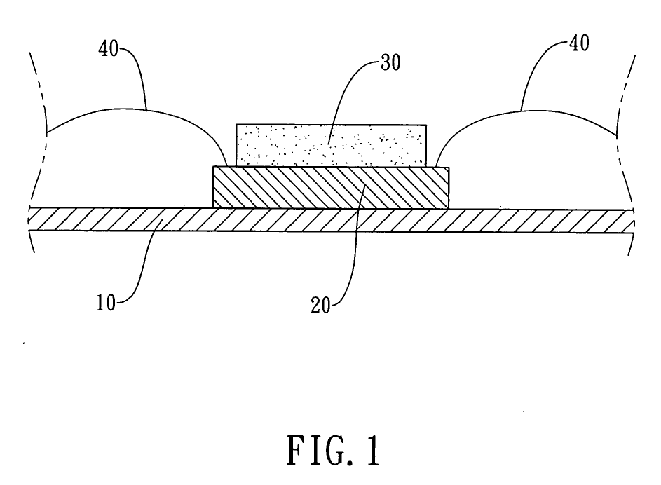

Referring to FIG. 1, in the present invention, an UV chip 20 is mounted on a bracing frame 10, wherein the UV chip 20 can emit the UV light that has a wavelength from 390 nm to 410 nm. Besides, a thin film 30 is stacked on the UV chip 20. The thin film 30 is a flat thin film formed by mixing a main agent and a solute uniformly, wherein the solute is fluorescent powder. Besides, in this preferred embodiment, the main agent is a glass, wherein if there is a need to electrically connect the UV chip 20 with the bracing frame 10 and other pins (not shown) by leading wires 40, the thin film 30 must be smaller than the UV chip 20 in size so as to expose the surface of the UV chip 20 for the connection of the leading wires 40. Thereafter, the assembly of the present invention is completed by covering these devices with a layer of transparent material.

When being electrified, the UV light is emitted from the UV chip 20 to pass through the flat thin film 30 formed by mixing the main agent and the solute uniformly. The thickness of the thin film 30 is uniform, the dispersion of the fluorescent powder in the thin film 30 is uniform, and the surface of the thin film 30 is at an identical distance from the UV light 20. As a result, if the thin film 30 is exited by the UV light, the uniform white light, which is free of photochromic difference and halation, can be generated.

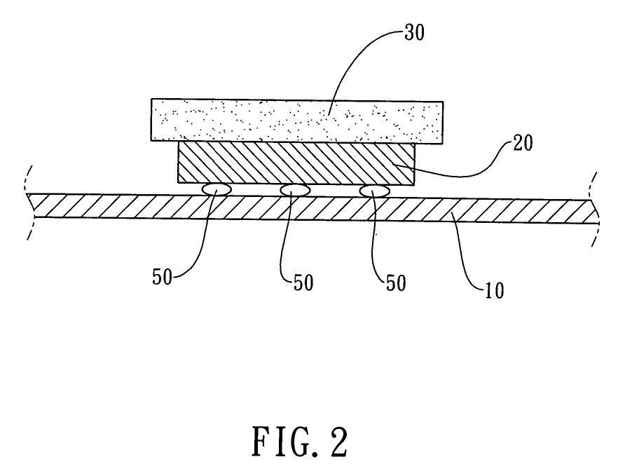

Referring further to FIG. 2, the UV chip 20 can be coupled with the bracing frame 10 through tin balls or gold balls by a flip-chip method. The tin balls are adopted in this preferred embodiment. As a result, the UV chip 20 is flipped and coupled with the bracing frame 10 through the tin balls 50 by the flip-chip method, and the thin film 30 is stacked on the UV chip 20. There is no need to perform the wire bonding process since the UV chip 20 is mounted by the flip-chip method. In this manner, the size of the thin film 30 can be equal to or larger than that of the UV chip 20.

In addition, the main agent of the thin film 30 can be silicon gel, epoxy resin, or epoxy resin containing silicon besides glass. Besides, the main agent can be made of transparent polymer or transparent plasticizer.

On the basis of the aforementioned description, it is apparent that the structure of the present invention provides the following advantages in which:

1. The thin film has uniform thickness and homogenized solute such that the uniform light color can be created when being staked on the UV chip.

2. The thin film is provided with homogenized solute such that the generated light is free of photochromic difference or halation if the thin film is exited by the UV light.

The white light LED of the present invention satisfies all requirements for a patent and is submitted for a patent.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments, which do not depart from the spirit and scope of the invention.

What the invention claimed is:

1. A white light LED, comprising:
a bracing frame;
at least an UV chip mounted on the bracing frame; and
a flat thin film stacked on the UV chip and formed by mixing a main agent and a solute uniformly for having uniform thickness and homogenized fluorescent powder, thereby forming uniform white light free of photochromic difference or halation by passing an UV light beam emitted from the UV chip through the thin film.

2. The white light LED of claim 1, wherein the main agent is glass.

3. The white light LED of claim 1, wherein the main agent is silicon gel.

4. The white light LED of claim 1, wherein the main agent is epoxy resin.

5. The white light LED of claim 1, wherein the main agent is epoxy resin containing silicon.

6. The white light LED of claim 1, wherein the UV light emitted from the UV chip is provided with a wavelength from 390 nm to 410 nm.

7. The white light LED of claim 1, wherein the thin film is smaller than the UV chip in size when coupling the UV chip by a wire bonding method.

8. The white light LED of claim 1, wherein the main agent is made of transparent polymer or transparent plasticizer.

9. A white light LED, comprising:
a bracing frame;
at least a blue light chip mounted on the bracing frame; and
a flat thin film stacked on the blue light chip and formed by mixing a main agent and a solute uniformly for having uniform thickness and homogenized fluorescent powder, thereby forming uniform white light free of photochromic difference or halation by passing a blue light beam emitted from the blue light chip through the thin film.

10. The white light LED of claim 9, wherein the main agent is glass.

11. The white light LED of claim 9, wherein the main agent is silicon gel.

12. The white light LED of claim 9, wherein the main agent is epoxy resin.

13. The white light LED of claim 9, wherein the main agent is epoxy resin containing silicon.

14. The white light LED of claim 9, wherein the blue light emitted from the blue light chip is provided with a wavelength from 450 nm to 480 nm.

15. The white light LED of claim 9, wherein the thin film is smaller than the blue light chip in size when coupling the blue light chip by a wire bonding method.

16. The white light LED of claim 9, wherein the main agent is made of transparent polymer or transparent plasticizer.
